(19) United States
(12) Patent Application Publication
(10) Pub. No.: US 2025/0336688 A1
(43) Pub. Date: Oct. 30, 2025

(54) MANUFACTURING METHOD OF NO-LEAD SEMICONDUCTOR PACKAGE COMPONENT

(71) Applicant: PANJIT ELECTRONICS (WUXI) CO., LTD., Wuxi (CN)

(72) Inventors: Jeff FANG, Jiangsu (CN); Cheng-Yu HSIA, Jiangsu (CN); Guangyu BAI, Jiangsu (CN)

(73) Assignee: PANJIT ELECTRONICS (WUXI) CO., LTD., Wuxi (CN)

(21) Appl. No.: 19/056,991

(22) Filed: Feb. 19, 2025

(30) Foreign Application Priority Data
Apr. 26, 2024 (CN) 202410511515.1

(51) Int. Cl. H01L 21/60; H01L 21/48; H01L 21/56; H01L 23/495

(52) U.S. Cl. CPC H01L 21/60; H01L 21/4828; H01L 21/565; H01L 23/49548; H01L 2021/6027

(57) ABSTRACT

A manufacturing method of no-lead semiconductor package component including: mounting a chip on a metal frame, wherein the metal frame includes two short metal connecting bars to allow the top metal contact and the bottom metal contact to be electrically connected to the two X-direction connecting metal bars, respectively, thereby performing bonding or soldering; performing a plastic package molding; cutting the Y-direction connecting bar by a first cutter so as to expose an entire of lateral surfaces of the plurality of metal contacts; applying a solderable metal layer on all of the plurality of metal contacts that are exposed by an electroplating process; and cutting off the plastic molding material by a second cutter whose diameter is smaller than a diameter of the first cutter to obtain a single semiconductor package component.

### CROSS-REFERENCE TO RELATED APPLICATIONS

This non-provisional application claims priority under 35 U.S.C. § 119 (a) on Patent Application No(s). 202410511515.1 filed in China, on Apr. 26, 2024, the entire contents of which are hereby incorporated by reference.

### TECHNICAL FIELD

The disclosure relates to the technical field of semiconductor package component, more particularly to the technical field of no-lead semiconductor package component.

### BACKGROUND

Quad Flat No-lead Package (QFN) uses traditional lead frame and is an advanced package component similar to Chip Size Package (CSP). It uses dual or quad flat no-lead package techniques having soldering pads only on bottom part and two sides and having advantages of small volume, light weight, excellent heat dissipation, excellent electrical performance and high reliability.

As shown in FIG. 1, traditional package in a type of metal contacts (Input/Output contacts) usually performs singulation on an entirely unit component by cutting after package process. After singulation, a component 1 exposes a bare copper bottom surface 20 of a lead 2 as a metal contact, and a lateral surface 21 of the lead 2 is flush with a side wall 10 of the component 1 as the metal contact. The current production merely applies a solder plating layer 3 on the bottom surface 20 of the lead 2 by electroplating. Thus, when the package unit is soldered on a circuit board 4, it is hard to determine the soldering point thereof by the appearance of the package unit based on such package configuration that replaces the conventional pins with the package in the type of metal contacts. In particular, the condition of the Tin on the bottom surface 20 can merely be known by a perspective mean, such as X-RAY, to determine the quality of the soldering process. In addition, metal contact of the lateral surface 21 of the lead 2 is exposed to the air and thus a non-wetting defect may be caused by oxidation.

In order to solve the above issue, the lateral surface 21 of the lead 2 is wetted by solder material, thereby realizing the creepage function of the metal contact of the lateral surface of the package unit. Currently, in a regular manner, traditionally, a step cut is performed on a lead frame firstly, and the electroplating creepage as shown in FIG. 2 on a side surface on which the cutting is performed on the lead frame applies the solder material to the metal contact of the lateral surface 21 by electroplating after cutting process, and finally the lead frame is singulated. The step cutting performed on the lead 2 is to ensure the metal units to be electrically connected in series, thereby facilitating the electroplating by maintaining complete electrical conduction. However, since step cutting or half cutting is performed on the metal connecting bar on lateral surface, the full creepage height of the metal contact on lateral surface can hardly be realized in the subsequent soldering process on the circuit board 4, where the creepage height of Tin material 6 depends on the cutting depth. In addition, since a half cutting is performed on the metal contact on lateral surface, the lateral surface 21 of the lead 2 has a step portion, and when the package unit is soldered on the circuit board 4, there may easily be a risk that the creepage height at the step portion is low and a risk that air 5 remains on the step portion.

Another regular manner is to perform full cutting on the lead frame 300 firstly. To allow the lateral surface bare metal that is cut off to be covered by solder material, an electroplating process is usually performed after cutting the lead frame 300, thereby covering the exposed metal by solder material. Thus, it should be ensured that the exposed metal pad is in the series circuit. For example, as shown by a schematic view showing the traditional lead connection in FIG. 3 (US patent publication numbered U.S. Pat. No. 9,640,463), each lead 30 is connected to a metal connecting bar 31 for connecting sixteen leads 30 in series to the metal frame 32 around the same, thereby allowing the electroplating process to be performed. However, in such manner, the number of the connection bars 31 depends on the number of the leads 30, which is strict to the demand for design, has complex manufacturing process and has low quality reliability.

Thus, an optimized cutting process and improved design of connecting bar of the lead frame 300 are required to improve the electrical conductivity and thermal conductivity of the lead frame 300 while effectively maximizing the creepage wetting area of metal contact on lateral surface and ensuring the reliability of the soldering process.

### SUMMARY

The disclosure solves technical problems by providing a manufacturing method of no-lead semiconductor package component, to ensure the stability and soldering quality of the soldering process when a package unit is soldered to a circuit board, so as to allow the package unit to be soldered more firmly and to simplify the inspection of soldering quality, thereby improving the competitiveness of the package unit by reducing inspection time and cost.

In order to solve the technical problems, the disclosure uses a manufacturing method of no-lead semiconductor package component including following steps:
mounting a chip on a metal frame, wherein the metal frame includes two Y-direction connecting metal bars and two X-direction connecting metal bars connected to one another, each of the two Y-direction connecting metal bars is electrically connected to a plurality of metal contacts, the plurality of metal contacts at least include a top metal contact and a bottom metal contact along Y-direction, the top metal contact and the bottom metal contact are electrically connected to the two X-direction connecting metal bars by being connected to two short metal connecting bars, respectively;
performing a plastic package molding on the metal frame where the chip is mounted by using a plastic molding material;
cutting the Y-direction connecting bar and cutting a part of the plastic molding material by a first cutter so as to allow the Y-direction connecting bar to expose an entire of lateral surfaces of the plurality of metal contacts;
applying a solderable metal layer on all of the plurality of metal contacts that are exposed by an electroplating process; and
cutting off the plastic molding material by a second cutter to obtain a single package unit, wherein a diameter of the second cutter is smaller than a diameter of the first cutter.

Due to the above technical solution, the disclosure has following advantages:

According to the manufacturing method of no-lead semiconductor package component provided by the disclosure, the metal contacts and the X-direction metal connecting bar are connected to one another. Thus, metal pads are allowed to be formed by half-etching process. In this way, on one hand, the soldering area of the wire bonding is enlarged. On the other hand, a cutout in step shape may be formed on the metal pads and the metal on the bottom surface. Therefore, the bonding strength of the lead and the plastic molding material is enhanced to improve the airtightness of the package component, thereby improving the stability and quality of the package unit.

In addition, all the metal contacts are in a series circuit, and the front surface and the rear surface of the chip adhered to the metal frame are connected on the metal frame via a ribbon or a clip. Thus, due to the equipotential principle, during the electroplating process, the front surface and the rear surface of the chip are in a short circuit condition, thereby realizing ESD protection function. Even though the electrical conduction on the metal frame along X-direction is disconnected by the cutting process, the disclosure further provides clamps for rack plating to form electrical connection in series, thereby simplifying the electroplating process.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic view showing traditional package of a type of metal contact;

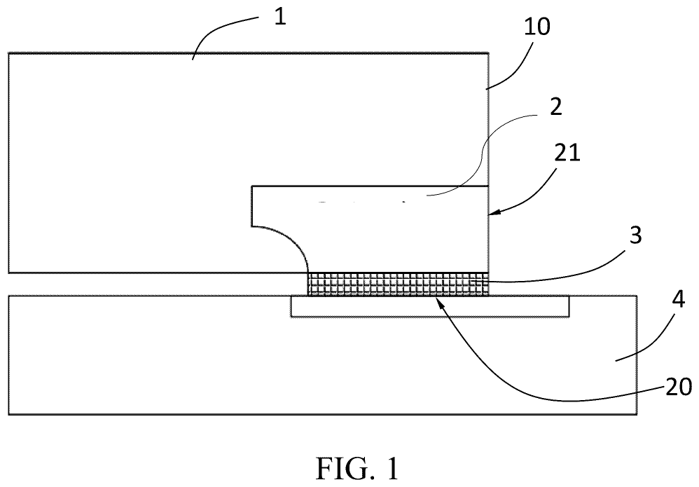

FIG. 2 is a schematic view showing an electroplating Tin material on a lateral surface where a traditional lead frame is cut;

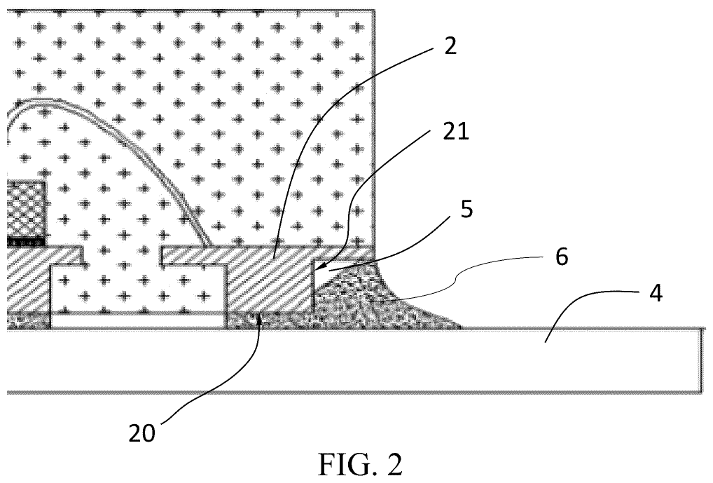

FIG. 3 is a schematic view showing a traditional lead connection;

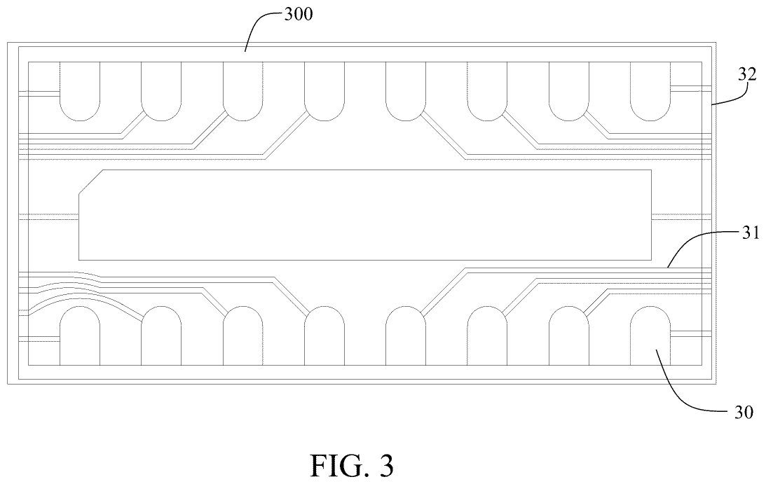

FIG. 4 is a flow chart showing a manufacturing process of the disclosure;

FIG. 5 is a schematic view showing a wetting effect of lateral metal contact of the disclosure;

FIG. 6 is a structural schematic view of a metal frame of the disclosure;

FIG. 7 is a rear structural schematic view showing a chip of the disclosure is mounted on the metal frame;

FIG. 8 is a rear structural schematic view of a package unit of the disclosure;

FIG. 9 is a front structural schematic view of a single package unit of the disclosure;

FIG. 10 is a schematic view showing the current during electroplating step of the disclosure;

FIG. 11 is a side view of the package unit of the disclosure after a plastic package molding is performed thereon;

FIG. 12 is a side view showing the cutting of a Y-direction long connecting bar of the disclosure;

FIG. 13 is a side view showing that a first cutting process of the disclosure is completed;

FIG. 14 is a side view showing that a plastic molding compound of the disclosure is cut;

FIG. 15 is a side view showing that a singulation of the disclosure is complete;

FIG. 16 is a side view showing a cutting direction of the Y-direction connecting bar of the disclosure;

FIG. 17 is a side view showing a cutting direction of the Y-direction plastic molding material, X-direction metal connecting bar and plastic molding material of the disclosure;

FIG. 18 is a top view of a metal frame of embodiment 1 of the disclosure when being embodied;

FIG. 19 is a schematic view of the metal frame in FIG. 18; and

FIG. 20 is a top view of a metal frame of embodiment 2 of the disclosure when being embodied.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

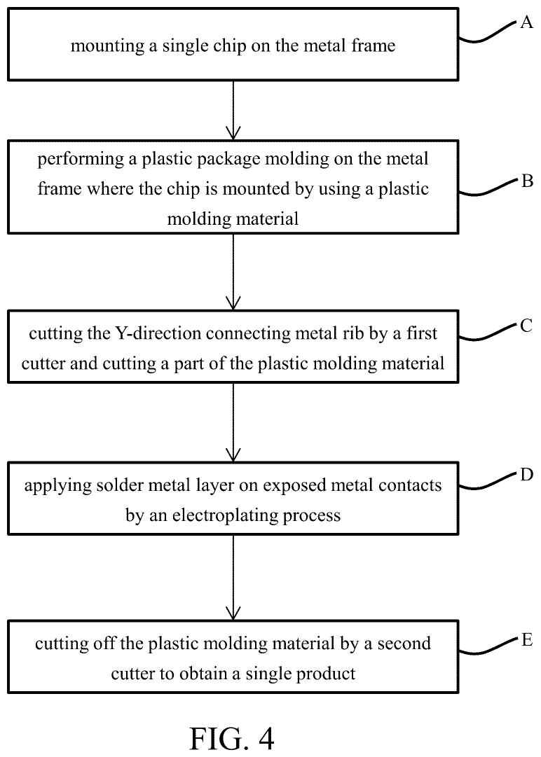

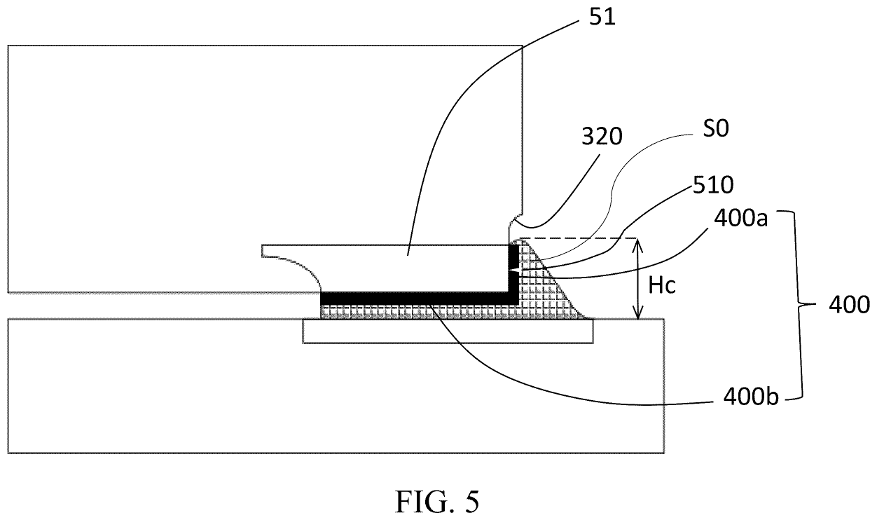

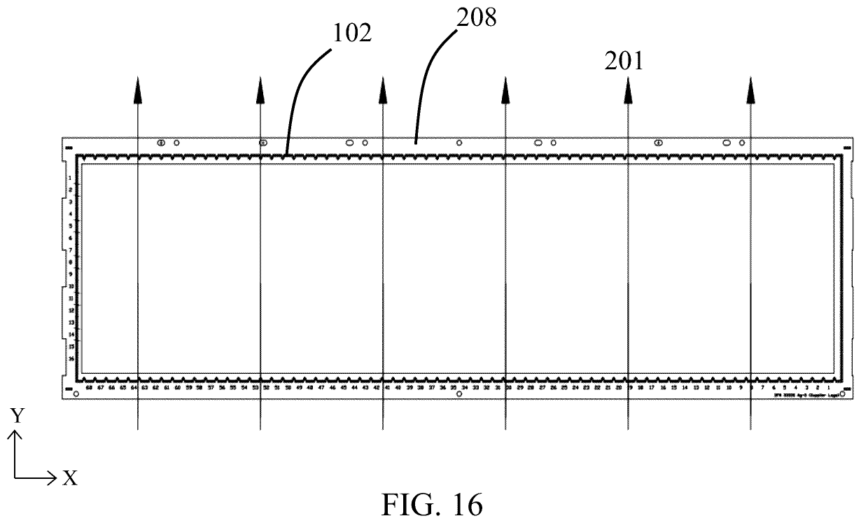

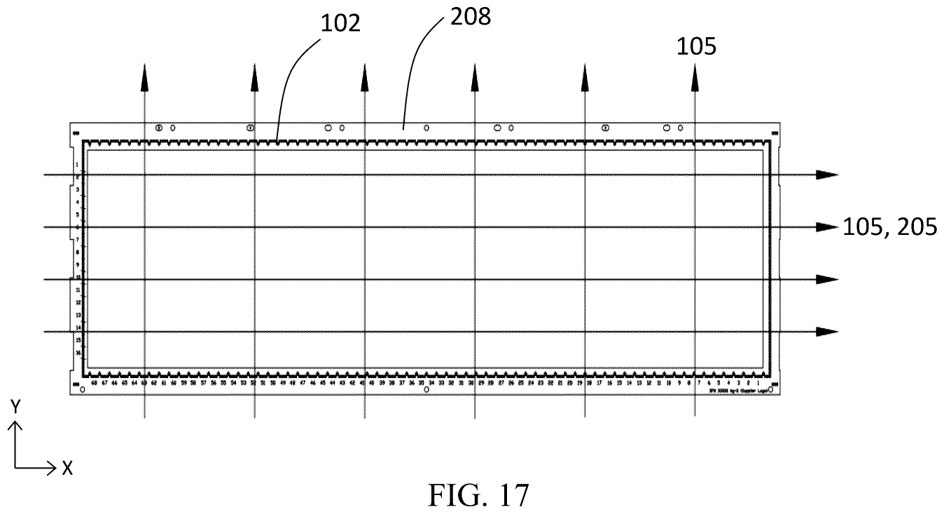

Please refer to FIG. 4 showing schematic flow chart of the disclosure, and the disclosure is further described in detail in combination with FIGS. 5 to 17 and specific embodiments.

Please refer to FIG. 5 that is a cross-sectional view taken along YZ plane. In order to allow the creepage height (Hc) to cover a height of a lateral surface 510 of a lead 51. The manufacturing method of no-lead semiconductor package component of the disclosure is to place a wafer into cutting machine to divide the wafer into multiple chips by diamond cutter, laser or the like, and then perform following steps:

Step A: mounting a single chip 101 on a matrix metal frame 102, and assembling the chip 101 to the matrix metal frame 102 via, for example, bond, solder bump or the like.

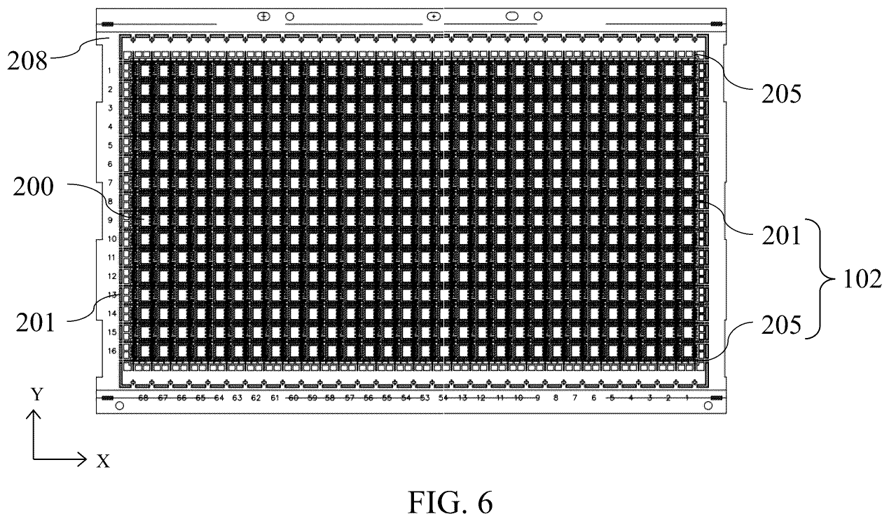

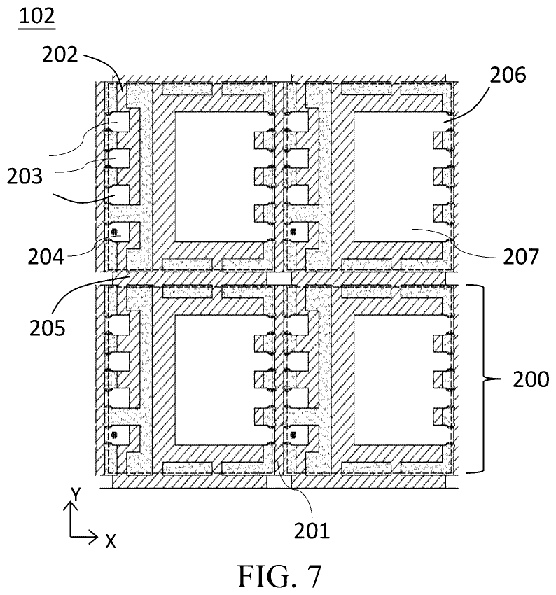

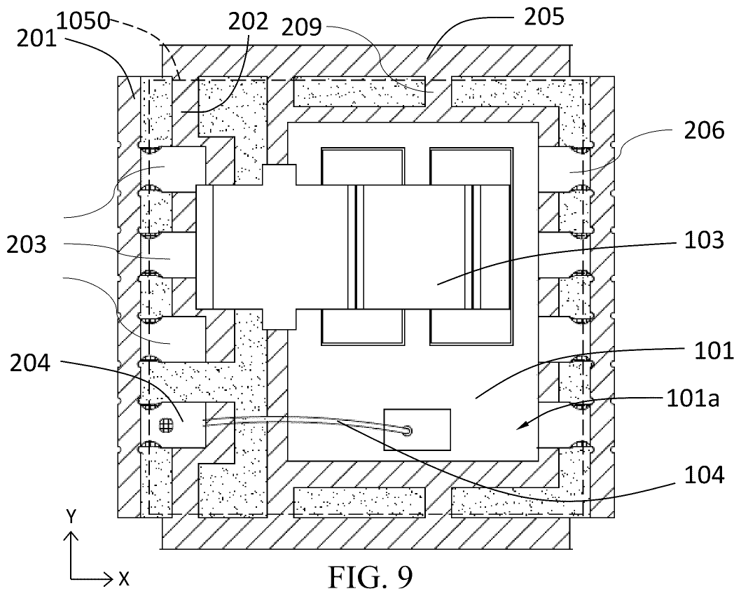

In specific embodiment, for example, as shown in FIGS. 6, 7 and 9, a plurality of package units 200 are disposed on the matrix metal frame 102. A peripheral of the matrix metal frame 102 is not covered by the plastic molding material and exposes an edge metal frame 208. The edge metal frame 208 is in, for example, a rectangle or square frame shape to surround the matrix metal frame 102, and connects X-direction connecting bars 205 and Y-direction connecting bars 201. After the chips 101 are mounted to the matrix metal frame 102 one by one, the Y-direction connecting bars 201 are electrically connected to the chips 101 respectively by left metal contacts (including left-top metal contacts 203 and a left-bottom metal contact 204) via a ribbon or a clip, thereby configuring a package unit 200. In FIGS. 7, 9 and 10, the white part denotes a part of the matrix metal frame 102 that is not etched, the part with section lines denotes a part of the matrix metal frame 102 that is etched, and the part with gray dots denotes a part of the metal frame that is hollow. Note that the package unit 200 may be referred as a semiconductor package component. The dotted line in FIG. 9 denotes, for example, an outer edge 1050 of the package unit 200.

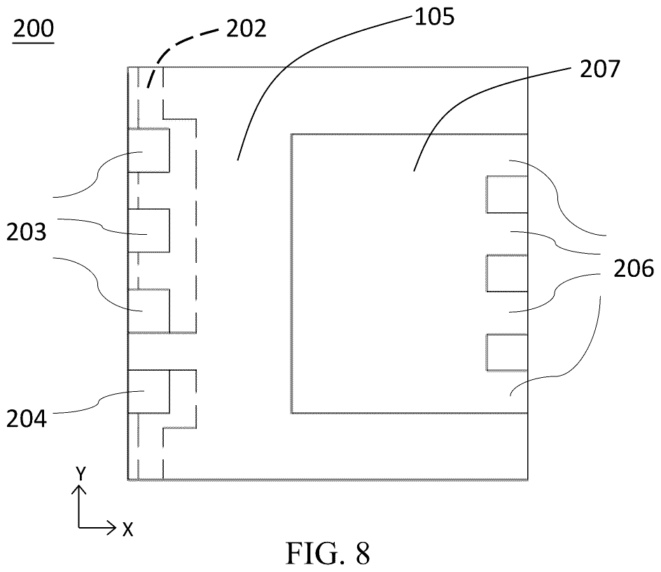

Next, referring to FIG. 8, a chip soldering area 207 is disposed inside the package unit 200. Four metal contacts are respectively disposed on left and right sides of the chip soldering area 207, including right metal contacts 206 and left metal contacts. The right metal contacts 206 is directly connected to the chip soldering area 207. Left metal contacts include three left-top metal contacts 203 connected to one another and one left-bottom metal contact 204. A short metal connecting bar 202 horizontal to the Y-direction connecting bars 201 is disposed to be connected to the left-top metal contacts 203, and another short metal connecting bar 202 is disposed to be connected to the left-bottom metal contact 204. Also, the two short metal connecting bars 202 respectively electrically connect two left metal contacts to the two X-direction connecting bars 205. The left-top metal contacts 203 and the left-bottom metal contact 204 are connected to the matrix metal frame 102 respectively via the short connecting bar 202 and the X-direction connecting bar 205. Due to such design, even though the Y-direction connecting bar 201 is cut off, the two left metal contacts still can be electrically connected to the top and bottom X-direction connecting bars 205 of the matrix metal frame 102 by the two short metal connecting bars 202. The dotted line in FIG. 8 denotes, for example, an outline of the etched part (denoted by section lines) of the Y-direction connecting bar 201 of the matrix metal frame 102 in FIG. 7.

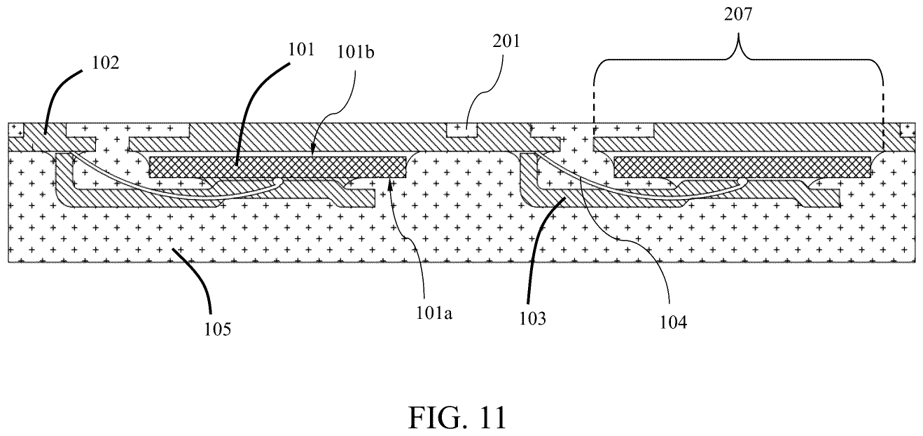

FIGS. 11 to 15 are, for example, cross-sectional views taken along XZ plane. Please refer to FIGS. 11 and 7 for the process of mounting the chip 101 on the matrix metal frame 102. First, the chip 101 is placed on the chip soldering area 207 of a front surface of the matrix metal frame 102, and a rear surface 101b of the chip 101 is bonded or soldered to the chip soldering area 207 of the matrix metal frame 102 via bonding or soldering process. Preferably, as shown in FIG. 9, a front surface 101a of the chip 101 and left metal contacts are respectively connected by a connecting structure, such as a clip 103 and a ribbon 104, by bonding or soldering manner.

In an embodiment, the clip 103 is preferably made of copper; the ribbon 104 is preferably made of gold, silver, copper, aluminum or an alloy. The ribbon 104 may be in a ribbon shape or a strip shape.

In an embodiment, further, by performing a half-etching technique on the three left-top metal contacts 203, a top part of the matrix metal frame 102 is removed to partially thin the matrix metal frame 102, thereby forming three metal pads whose bottom parts are connected. The matrix metal frame 102 where the half-etching is performed may enhance the bonding strength of the matrix metal frame 102 and the plastic molding material 105, and reduce the rick of the delamination of the package unit.

Step B: performing a plastic package molding on the matrix metal frame 102 where the chip 101 is mounted by using a plastic molding material 105. Note that the plastic molding material 105 is omitted from FIGS. 6 and 7.

Nest, please refer to FIGS. 11 and 8. A plastic package is performed on the matrix metal frame 102 where the chip is soldered using the plastic molding material 105, and each package unit 200 is entirely surrounded by the plastic molding material 105. Each package unit 200 includes the chip 101, the metal contacts (including the left-top metal contacts 203, the left-bottom metal contact 204 and the right metal contacts 206), the ribbon 104 and the clip 103. The plastic package molding is to complete the plastic package by injecting encapsulants, and then the matrix metal frame 102 and the chip soldering area 207, the Y-direction connecting bars 201 and the X-direction connecting bars 205 located thereon are entirely surrounded by the plastic molding material 105. Only a peripheral of the matrix metal frame 102 is not surrounded by the plastic molding material, and the edge metal frame 208 is exposed to the outside to facilitate the subsequent cutting process. The plastic molding material 105 may be made of epoxy, ABF resin or other types of plastic molding material.

Step C: cutting the Y-direction connecting bar 201 and cutting a part of the plastic molding material 105 so as to expose an entire of the lateral surfaces of the metal contacts.

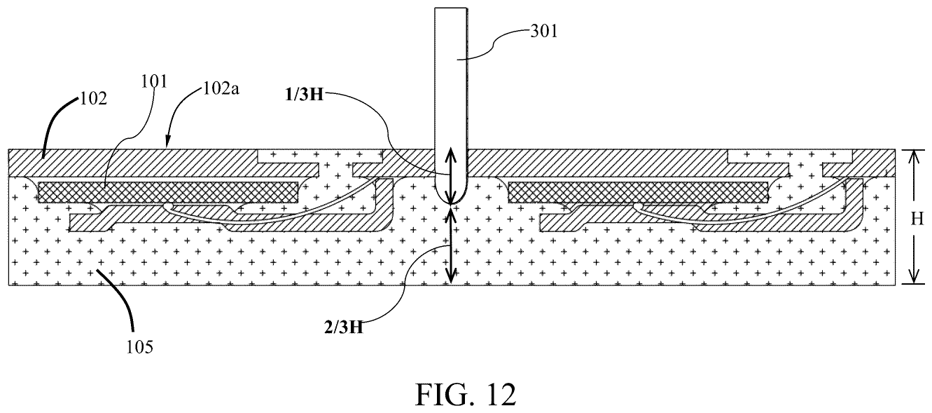

Please refer to FIGS. 12, 13 and 16. A cutter 301 is used to cut the matrix metal frame 102 surrounded by the plastic molding material 105 along a direction from a bottom surface 102a of the matrix metal frame 102 to the chip 101, to perform vertical cut to cut off the Y-direction connecting bar 201 until a part of the plastic molding material 105 is cut without cutting off the plastic molding material 105, thereby forming a scribe line 106. A cutting depth H2 is preferably equal to ⅓ of a body thickness H of the package unit 200, and the remaining thickness H3 is ⅔ of body thickness H and forms the scribe line 106 as reference scribe line for last singulation process. The cutter 301 cuts a part of the plastic molding material 105 to form a cutout 320 allowing the Y-direction connecting bar 201 to be entirely cut off and allowing multiple metal contacts of the Y-direction connecting bar 201 to entirely expose lateral surfaces (referring to FIG. 7).

Step D: applying solderable metal layer 400 on all exposed metal contacts and rear surface and lateral surface of the matrix metal frame 102 by an electroplating process.

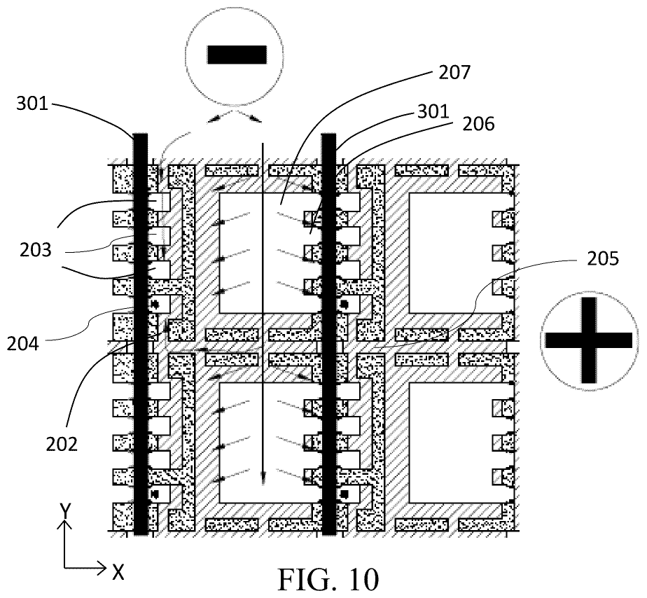

Please refer to FIG. 10. The Y-direction connecting bar 201 is entirely cut off in the step C, the three left-top metal contacts 204 spaced apart from one another are electrically connected to the short metal connecting bar 202, so as to allow the current flowing from the top X-direction connecting bar 205 to form series circuit, thereby realizing lateral and vertical electrical conduction by the left-top metal contacts 203. Also, the current flowing from the bottom X-direction connecting bar 205 flows to the left-bottom metal contact 204 through the short metal connecting bar 202, thereby realizing lateral and vertical electrical conduction. In addition, the four right metal contacts 206 located on a side of the chip soldering area 207 are also allowed to receive the current flowing from the X-direction connecting bar 205, thereby completing the electroplating. It is ensured that the left metal contacts are electrically connected to the top and bottom X-direction connecting bars 205 respectively via the two short metal connecting bars 202 even after the electrical connection along Y-direction is disconnected after the cutting process in the step C. Thus, the electrical conduction between the left metal contacts and other components are maintained so that the electroplating is allowed to be performed by a current barrel, thereby ensuring a solderable metal layer 400 to be applied to all of the metal contacts whose electrical conduction is maintained. In addition, for example, the positive label in FIG. 10 corresponds to an anode of an electroplating apparatus and the negative label in FIG. 10 correspond to a cathode of the electroplating apparatus. Even when the Y-direction connecting bars 201 are cut off, the edge metal frame 208 is still not cut off. Thus, the edge metal frame 208 respectively connects the anode and the cathode of the electroplating apparatus at different directions, so as to function as a conductive pathway for electricity on or for current to flow thereon.

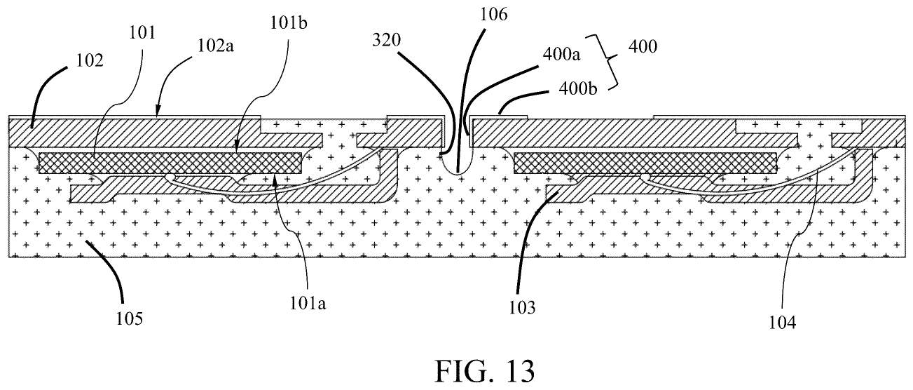

Next, please refer to FIGS. 5 and 13. The electroplating is preferably implemented by rack plating or high-speed plating, allowing a lateral solderable metal layer 400a to be applied on an entire of the lateral surface bare copper exposed after cutting the Y-direction connecting bar 201 and allowing a bottom solderable metal layer 400b to be applied and covered on the bottom surface 102a of the matrix metal frame 102.

Please refer to FIGS. 9 and 11. Furthermore, the front surface 101a of the chip 101 adhered on the matrix metal frame 102 is electrically connected to the left metal contacts 203 via the ribbon 104 or the connecting sheet 103, the left metal contacts 203 is electrically connected to the X-direction connecting bar 205 via the short metal connecting bar 202, the X-direction connecting bar 205 is electrically connected to the chip soldering area 207 via the connecting bar 209, and the rear surface 101b of the chip 101 is electrically connected to the chip soldering area 207 of the matrix metal frame 102. Thus, the front surface 101a and the rear surface 101b of the chip 101 are in a short circuit condition by the connection of the matrix metal frame 102. Due to the equipotential principle, during the electroplating process, the chip realizes ESD protection function.

Step E: cutting off the plastic molding material 105 by thin cutter 302 to obtain a single package unit.

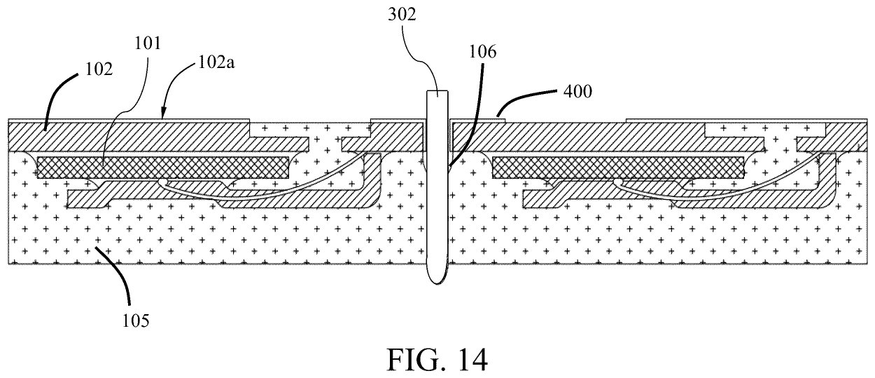

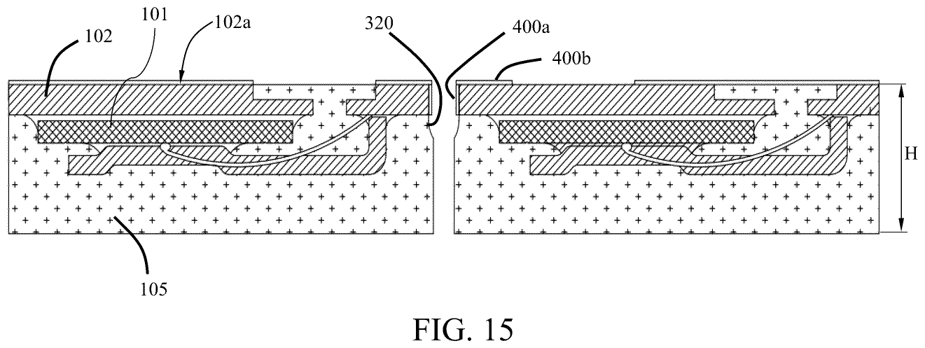

Next, please refer to FIGS. 14, 15 and 17. A full cut is performed to cut the electroplated package component by the thin cutter 302 whose diameter is smaller than the diameter of the cutter 301 preferably along the scribe line 106 from the side of the matrix metal frame 102, to entirely cut off the plastic molding material 105 along Y-direction and entirely cut off the plastic molding material 105 and the X-direction connecting bar 205 along X-direction. Since the diameter of the thin cutter 302 is smaller than the width of the scribe line 106, a single package unit 200 as shown in FIG. 15 is obtained after the full cut. A wall surface of the cutout 320 adjoining the plastic molding material 105 and the Y-direction connecting bar 201 is correspondingly recessed inwards along a thickness direction from the lateral solderable metal layer 400a, and the cutout 320 is located on a position at ⅓ of body thickness H of the package unit 200, where ⅓ of body thickness H ranges, for example, from 0.2 mm to 0.4 mm, preferably from 0.22 mm to 0.35 mm. The bottom part and lateral surface of the Y-direction connecting bar 201 both are covered with solder metal material. Thus, when a part of the bottom surface 102a and the lateral surface of the matrix metal frame 102 is wetted by solder material (referring to FIG. 5, the lead 51 in FIG. 5 corresponds to the left-top metal contact 203 exposed after the Y-direction connecting bar 201 is entirely cut off in FIG. 7), the solder material SO covers the lateral solderable metal layer 400a and the bottom solderable metal layer 400b. Also, due to the cutout 320 recessed inwards from the peripheral wall of the plastic molding material 105, the creepage height Hc of the solder material SO on the lead 51 along the lateral solderable metal layer 400a on the lateral surface 510 may be higher than a height of the lead 51, thereby allowing the lateral surface of the lead 51 to be entirely covered with Tin material and improving the mechanical stress resistance.

### Embodiment 1

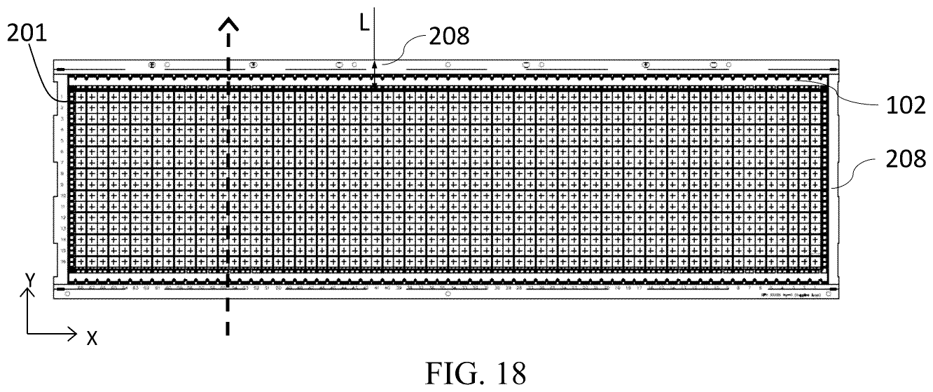

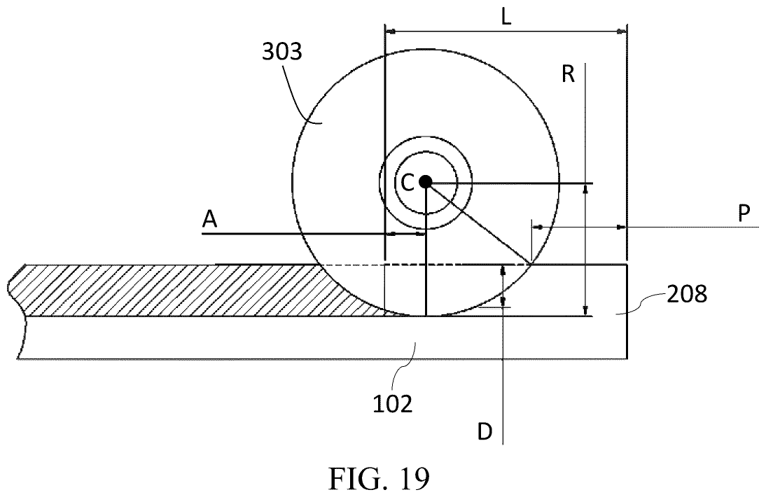

Please refer to FIG. 18. In this embodiment, a Y-direction width L of the X-direction edge metal frame 208 of the matrix metal frame 102 is wider. In step C, after cutting off the Y-direction connecting bar 201, only ⅓ of body thickness of the package unit 200 is cut and the cutting process ends, which prevents the edge metal frame 208 from being cut off. Please refer to FIG. 9. After the cutting process is completed, the left metal contacts of each unit are entirely exposed, and the left metal contacts are connected to the X-direction connecting bar 205 via the short connecting bar 202. Meanwhile, the short connecting bar 202 may be function as a Y-direction connecting wire to ensure all the metal contacts are in the electrical conduction circuit along Y-direction and each package unit 200 is connected via the rear plastic molding material 105. The rear plastic molding material 105 on the matrix metal frame 102 covered with the plastic molding material 105 is not cut off, and the X-direction edge metal frame 208 is not cut off, thereby facilitating the subsequent electroplating and second cutting step. The Y-direction width L of the X-direction edge metal frame 208 and a part of the matrix metal frame 102 is adjusted by, for example, cutting parameters to omit the clamps for rack plating. For example, as shown in FIG. 19, the Y-direction width L meets the following inequality:

$$L \geq \sqrt{{R}^{2} - {( R - D )}^{2}} + A + P$$

In the above inequality, L is Y-direction width L of the X-direction edge metal frame 208 and a part of the matrix metal frame 102, R is the radius of the cutter 301, D is the cutting depth of the cutter 301, A is a safety margin width, and P is electroplating preserved width. In addition, in FIG. 19, the cutter 301 has a central point C. The radius R of the cutter 301 generally ranges from 25 mm to 35 mm. The cutting depth D generally ranges from 0.2 mm to 0.4 mm, preferably ranges from 0.22 mm to 0.35 mm. The safety margin width A generally ranges from 0.3 mm to 0.7 mm, preferably is 0.5 mm. The electroplating preserved width P generally ranges from 0.22 mm to 1.2 mm, preferably is 1 mm.

### Embodiment 2

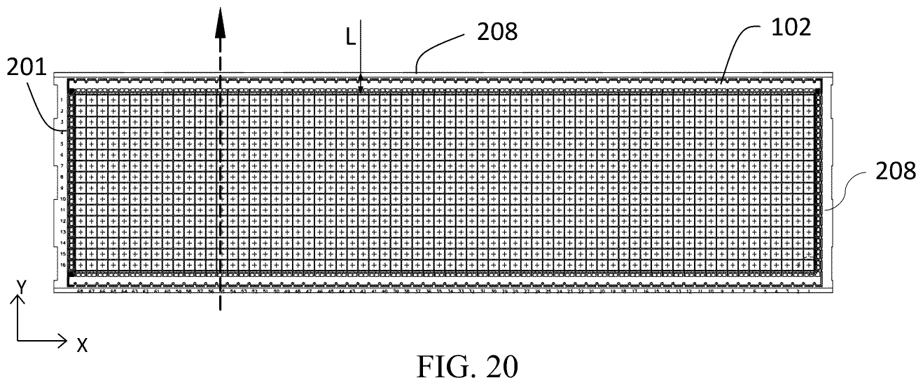

Please refer to FIG. 20. In this embodiment, the Y-direction width of the X-direction edge metal frame 208 of the matrix metal frame 102 is narrower. This embodiment are substantially the same and embodiment 1, except that: in step C, after the Y-direction connecting bar 201 is cut off, the Y-direction width of the X-direction edge metal frame 208 is too narrow (additionally referring to FIG. 19, that is, Y-direction width L meets the following inequality: L≥\sqrt{R²−(R-D)²}+A+P). Thus, the edge metal frame 208 is easily cut off to destroy the electrical conduction in the subsequent electroplating process. Thus, to maintain the electrical connection of the matrix metal frame 102 in series, clamps for rack plating are used in this embodiment to clamp the X-direction edge metal frame 208 that is cut off, thereby maintaining the X-direction connecting bar 205 to be electrically connected to the two short connecting bars 202. Further, since the short connecting bar 202 is a connecting medium, even though the X-direction edge metal frame 208 is cut off, the left metal contacts may still be in the series circuit and be covered by solder metal material in the electroplating process.

In summary, the present disclosure triples practical soldering area since the bottom parts of the left-top metal contacts 203 are electrically connected, and the heat dissipation capability of the package unit is enhanced. Meanwhile, the metal pads have cutout in step shape, and thus the bonding strength of the metal frame and the plastic molding material is enhanced to improve the airtightness of the package component, thereby improving the stability and quality of the package unit.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A manufacturing method of no-lead semiconductor package component, comprising:
mounting a chip on a metal frame, wherein the metal frame comprises two Y-direction connecting metal bars and two X-direction connecting metal bars connected to one another, each of the two Y-direction connecting metal bars is electrically connected to a plurality of metal contacts, the plurality of metal contacts at least comprise a top metal contact and a bottom metal contact along Y-direction, the top metal contact and the bottom metal contact are electrically connected to the two X-direction connecting metal bars by being connected to two short metal connecting bars, respectively;
performing a plastic package molding on the metal frame where the chip is mounted by using a plastic molding material;
cutting the Y-direction connecting bar and cutting a part of the plastic molding material by a first cutter so as to allow the Y-direction connecting bar to expose an entire of lateral surfaces of the plurality of metal contacts;
applying a solderable metal layer on all of the plurality of metal contacts that are exposed by an electroplating process; and
cutting off the plastic molding material by a second cutter to obtain a single semiconductor package component, wherein a diameter of the second cutter is smaller than a diameter of the first cutter.

2. The manufacturing method of no-lead semiconductor package component according to claim 1, wherein in the step of the plastic package molding, a plurality of package units are further disposed on the metal frame to be electrically connected to the Y-direction connecting bar and the X-direction connecting bar, a chip soldering area is disposed on each of the plurality of package units, and four of the plurality of metal contacts are disposed on a left side and a right side of the chip soldering area, respectively.

3. The manufacturing method of no-lead semiconductor package component according to claim 2, wherein in the step of mounting the chip on the metal frame, a rear surface of the chip is further bonded or soldered to the chip soldering area of the metal frame.

4. The manufacturing method of no-lead semiconductor package component according to claim 1, wherein in the step of mounting the chip on the metal frame, a front surface of the chip is further bonded to be connected to the top metal contact by a clip.

5. The manufacturing method of no-lead semiconductor package component according to claim 1, wherein in the step of mounting the chip on the metal frame, a front surface of the chip is further soldered to be connected to the bottom metal contact by a ribbon.

6. The manufacturing method of no-lead semiconductor package component according to claim 1, wherein in the step of cutting the Y-direction connecting bar by the first cutter, a cutting depth is equal to ⅓ of a thickness of the semiconductor package component.

7. The manufacturing method of no-lead semiconductor package component according to claim 1, wherein in the step of cutting the Y-direction connecting bar by the first cutter, the Y-direction connecting bar is further cut until a part of the plastic molding material is cut to form a cutout along a direction from the side of the metal frame to the plastic molding material, the cutout entirely cuts off the Y-direction connecting bar and does not cut off the plastic molding material.

8. The manufacturing method of no-lead semiconductor package component according to claim 7, wherein the cutout of the plastic molding material adjoins the Y-direction connecting bar, and the cutout is correspondingly recessed inwards along a thickness direction from the solderable metal layer from a peripheral wall of the plastic molding material.

9. The manufacturing method of no-lead semiconductor package component according to claim 1, wherein in the step of electroplating, the solderable metal layer is further formed on a bottom surface of the metal frame.

10. The manufacturing method of no-lead semiconductor package component according to claim 1, wherein in the step of cutting off the plastic molding material by the second cutter, the plastic molding material of Y-direction, the plastic molding material of X-direction and the X-direction connecting bar are further entirely cut off.

11. The manufacturing method of no-lead semiconductor package component according to claim 3, wherein after the step of being bonded or soldered to the metal frame, a bottom part of the metal frame is thinned by a half-etching.

12. The manufacturing method of no-lead semiconductor package component according to claim 1, wherein in the step of electroplating, the solderable metal layer is further formed on an exposed lateral surface of the metal frame.

13. The manufacturing method of no-lead semiconductor package component according to claim 1, wherein in the step of electroplating, a bottom solderable metal layer is further formed on a bottom part of the Y-direction connecting metal bar, and a lateral solderable metal layer is further formed on a lateral surface of the Y-direction connecting metal bar.

14. The manufacturing method of no-lead semiconductor package component according to claim 13, wherein a creepage height of the lateral solderable metal layer is higher than a thickness of the metal frame.

15. The manufacturing method of no-lead semiconductor package component according to claim 13, wherein the cutout of the plastic molding material is correspondingly recessed inwards from the side solderable metal layer.

16. The manufacturing method of no-lead semiconductor package component according to claim 1, wherein in the step of electroplating, a device for rack plating is further used to clamp the metal frame of X-direction.

17. The manufacturing method of no-lead semiconductor package component according to claim 1, wherein in the step of electroplating, a device for rack plating is further used to realize an electrical conduction of the X-direction connecting metal bar.

18. The manufacturing method of no-lead semiconductor package component according to claim 1, wherein in the step of cutting the Y-direction connecting bar by the first cutter, the plastic molding material is not cut off to form a scribe line, and the diameter of the second cutter is smaller than a width of the scribe line.

19. The manufacturing method of no-lead semiconductor package component according to claim 4, wherein in the step of the plastic package molding, the plastic molding material surrounds the chip, the plurality of metal contacts and the clip.

20. The manufacturing method of no-lead semiconductor package component according to claim 5, wherein in the step of the plastic package molding, the plastic molding material surrounds the chip, the plurality of metal contacts and the ribbon.
